(19) United States
(12) Patent Application Publication
(10) Pub. No.: US 2001/0003377 A1
(43) Pub. Date: Jun. 14, 2001

(54) HEAT SINK FOR A SEMICONDUCTOR DEVICE

(76) Inventors: MYOUNG KI YOO, SEOUL (KR); YOUNG-JOON BAIK, SEOUL (KR); KYUNG TAE HONG, SEOUL (KR)

Correspondence Address: SCULLY SCOTT MURPHY & PRESSER, 400 GARDEN CITY PLAZA, GARDEN CITY, NY, 11530

(21) Appl. No.: 09/357,058

(22) Filed: Jul. 19, 1999

(30) Foreign Application Priority Data
Jul. 28, 1998 (KR) 30343-1998

(51) Int. Cl. H01L 23/34

(52) U.S. Cl. 257/712

(57) ABSTRACT

A heat sink for a semiconductor device comprises a tungsten-copper composite body and a diamond film coated on the surface of the body. A method for fabricating a heat sink for a semiconductor comprises the steps of fabricating a tungsten-copper composite heat sink, modifying a surface of the heat sink by selectively dissolving copper from the surface of the heat sink, carrying out a process for supplying nuclei for growth of a diamond film on the modified surface of the heat sink, and coating the thusly processed surface of the heat sink with a diamond film. Preferably, a process for etching of a tungsten grain precedes selective dissolution of the copper.

### BACKGROUND OF THE INVENTION

1. Field of the Invention

The present invention is directed to a heat sink and a fabricating method therefor, and in particular to a composite heat sink having high thermal conductivity, which is employed for the packaging of a high power semiconductor device for mobile communication, satellite communications and optical communications, such as a microwave semiconductor device operating in a frequency band of a few to several tens of GHz and a laser diode operating at a data communication rate in the Gbps level, and to a fabricating method therefor.

2. Description of the Background Art

Semiconductor chips used for mobile communications, satellite communications and optical communications are typically mounted on a thermally conductive material (heat sink), and a hermetic packaging is carried out in order to protect the chip and its constitutional circuitry from the external environment. [M. Tsujioka et al.: U.S. Pat. No. 5,574,959 / T. Arikawa et al.: U.S. Pat. No. 5,493,153 / C. Patel: U.S. Pat. No. 5,396,403 / M. Medeiros et al.: U.S. Pat. No. 5,188,985 / M. Osada et al.: U.S. Pat. No. 5,099,310 / Michael R. Ehlert et al.: U.S. Pat. No 4,788,627]. In case the semiconductor chip is mounted on the heat sink by die attaching, bonding between the semiconductor chip and the heat sink is carried out with a brazing or soldering generally. The bonding material serves to absorb stress generated due to the difference in thermal expansion coefficient between the chip and the heat sink. Generally, the heat sink has a lower thermal expansion coefficient than the chip. In addition, in order to externally constitute a circuit, the interconnections between the die and the heat sink are isolated by an insulation structure composed of ceramic or glass such as Al₂O₃, BeO and the like. Then, terminals and leads are insulated from the heat sink, and at the same time wired with the semiconductor device for an external wiring. In order to protect the circuit, a packaging is carried out for sealing an upper portion thereof by a lid.

Especially, a semiconductor device for mobile communication or satellite communication, such as a GaAs FET, MMIC or the like which is operated in a frequency band of a few to several tens of GHz, and a semiconductor device for optical communication at a several Gbps level are fabricated as an out-sourceable module by carrying out a packaging for internally having a spatial structure therein. The heat sink which is of a thermally conductive material composing the package serves to externally dissipate heat generated from the chip and maintain the performance of the chip. A tungsten composite and a molybdenum composite containing copper and nickel have been recently employed as the thermally conductive material. [Frank J. Polese et al.: U.S. Pat. No. 5,413,751 / M. Osada et al.: U.S. Pat. No. 5,409,864 / Mark R. Schneider: U.S. Pat. No. 5,172,301 / John L. Johnson et al.: Tungsten and Refractory Metals - 1994 MPIF, Princeton, N.J., 1995, p.245]. That is, copper-tungsten or -molybdenum composites are used as a heat sink for the purpose of improving the heat conductivity together with a thermal expansion coefficient similar to the semiconductor chip (GaAs, Si) or Al₂O₃ by combining the properties of tungsten (W) or molybdenum (Mo) having a low thermal expansion coefficient with the properties of copper (Cu) having a high thermal expansion coefficient and a high thermal conductivity.

However, the differences in the melting point and specific gravity between the above-mentioned materials are high, and thus uniform and sound microstructures cannot be obtained by a melting process. Therefore, the composite is produced by a powder metallurgy. In general, a tungsten powder or a tungsten-nickel composite powder further comprising nickel in order for its weight ratio not to exceed 1.0% is compacted (or preformed) and sintered, thereby fabricating a porous skeleton structure. Then, a copper liquid phase is infiltrated thereunto. In another process, a tungsten, copper, nickel or cobalt composite powder and/or mixed powder thereof is compacted, and a liquid phase sintering is carried out thereon [Nathaniel R. Quick and James C. Kenney: U.S. Pat. No. 5,184,662 / Lloyd F. Neely: U.S. Pat. No. 3,992,199/ Radall M. German: Sintering Technology and Practice, John Willey & Sons, Inc., N.Y., 1996, p. 237 / M. M. Parikh and M. Humenik, Jr.: J. Amer. Ceram, Sco., vol. 40, 1957, p. 320]. In order to improve the homogeneity of the microstructures, a ball milling process is employed [Moon-Hee Hong et al.: Proc. 13th Inter. Plansee Seminar, vol. 1, Metallwerk Plansee, Reutte, 1993, p.451], or a cyclic heat treatment process is subsequently used [Jong-Koo Park et al.: The Korean Patent Publication No. 96-15218].

Recently, a powder injection molding process is used for a net shaping [B. Yang and Randall M. German: Inter. J. Powder Metall., vol. 33, 1997, p. 55 / James B. Oenning et al.: U.S. Pat. No. 4,988,386]. According to the powder injection molding process, at a forming step a metal powder and a polymer binding agent are mixed together, and are injection-molded into a predetermined shape, and a debinding process for removing the polymer binding agent is carried out thereon, and thus, a shaped body composed of the metal powder is fabricated, and thereafter a copper liquid phase is infiltrated or a liquid phase sintering is carried out.

However, the sintering conditions for the net shaping and the infiltration or heat treatment conditions for obtaining a uniformly fine microstructure are dependent upon the shape to be fabricated, an average particle (or powder) size and size distribution of a raw material powder, and the composition of the copper. For instance, in case the copper content is increased to improve the thermal conductivity, it is difficult to control the shape because the amount of the liquid phase is increased. When a solid phase skeleton structure for infiltration is fabricated by using tungsten powder having a large average particle size, a high sintering temperature is required. In addition, in the case that nickel is added in order to lower the sintering temperature, the added nickel and the copper are soluble, thereby reducing the thermal conductivity of the copper.

### SUMMARY OF THE INVENTION

It is therefore a primary object of the present invention to provide a heat sink which can efficiently dissipate heat generated during the operation of a semiconductor device, and which has a low thermal expansion coefficient and which can be used for a high power semiconductor and a high thermal conduction, in order to protect a circuit composing the device or module from an external environment, such as moisture and electromagnetic interference of a frequency band of a few to several tens of GHz.

It is another object of the present invention to provide a method of coating a diamond film for a surface on which a chip is mounted or a heat emitting portion, in order to net-shape a tungsten-copper composite as a material for a heat sink of a high power semiconductor device or laser diode, and improve its thermal conductivity.

In order to achieve the above-described objects of the present invention, there is provided a heat sink for a semiconductor device comprising a tungsten-copper composite body and a diamond film coated on the surface of the body.

In addition, there is provided a method for fabricating a heat sink for a semiconductor comprising the steps of fabricating a tungsten-copper composite heat sink, modifying a surface of the heat sink by selectively dissolving copper from the surface of the heat sink, carrying out a process for supplying nuclei for growth of a diamond film on the modified surface of the heat sink and coating the thusly processed surface of the heat sink with a diamond film

Here, a process for etching of a tungsten grain preferably precedes selective dissolution of the copper, and the copper is preferably dissolved in an aqueous acid solution comprising HNO₃, and the process for supplying nuclei for growth of the diamond film is carried out preferably in an acetone solution containing fine diamond powder, and the process for etching the tungsten grain is carried out preferably in a Murakami solution (potassium ferricyanide [K₃Fe(CN)₆]+sodium hydroxide[NaOH]+water[H₂O]).

Additional preferred embodiments of the present invention may be obtained in accordance with the contents recited in the dependent claims of the present invention.

### BRIEF DESCRIPTION OF THE DRAWINGS

The present invention will become better understood with reference to the accompanying drawings, which are given only by way of illustration and thus are not limitative of the present invention, wherein:

FIGS. 1a to 1c are perspective views which respectively illustrate constitutional elements of a package for a microwave semiconductor device, which are composed of a tungsten-copper composite produced by a powder injection molding process, wherein:

FIG. 1a illustrates a plate-shaped heat sink which is the object of the present invention;

FIG. 1b illustrates a bottom plate for a container for packaging a high power semiconductor device which has a walled space structure; and

FIG. 1c illustrates a metal header for mounting a laser diode;

FIG. 2 illustrates an exemplary microstructure taken along line C-C′ in FIGS. 1a to 1c;

FIGS. 3a and 3b are schematic cross-sectional views illustrating the change in surface morphology of the heat sink of FIG. 1a after chemical etching, wherein:

FIG. 3a illustrates a state after selectively dissolving copper; and

FIG. 3b illustrates a state after modifying the surface of the heat sink by chemical etching of tungsten grain followed by dissolution of copper;

FIG. 4 illustrates a state of coating the surface in FIG. 3b with a diamond film;

FIG. 5 is a cross-sectional view which schematically illustrates a heat sink coated with a diamond film in accordance with the present invention is used in a plastic package for a semiconductor device;

FIGS. 6a and 6b are perspective views respectively illustrating another embodiment of a heat sink coated with a diamond film in accordance with the present invention, wherein:

FIG. 6a illustrates a state of bonding a plate-shaped heat sink coated with a diamond film in accordance with the present invention to the space for the heat sink in the bottom plate of a container for packaging a high power semiconductor device of FIG. 1b; and

FIG. 6b illustrates a state of bonding a plate-shaped heat sink coated with a diamond film in accordance with the present invention to the space for the heat sink in the metal header for mounting a laser diode of FIG. 1c.

### DETAILED DESCRIPTION OF THE INVENTION

As above mentioned, the present invention is characterized by coating the chip-locating surface or heat-dissipating portion of a heat sink with a diamond film, in order to improve the thermal conductivity of a tungsten-copper composite that is a material for dissipating heat generated during the operation of a high power semiconductor device and laser diode. According to the present invention, a feed stock is fabricated by mixing pure tungsten powder with a polymer binder without adding a transition metal, such as nickel, cobalt or the like. A preform of a skeleton structure is fabricated by injection molding the feed stock and then debinding to remove the polymer binder and subsequently by sintering the debinded part and thus net-shaped forms are thusly obtained by infiltrating a copper liquid phase thereunto, and then the surface of the obtained heat sink is modified by chemical and/or physical treatment, and thereafter the modified surface is coated with a diamond film.

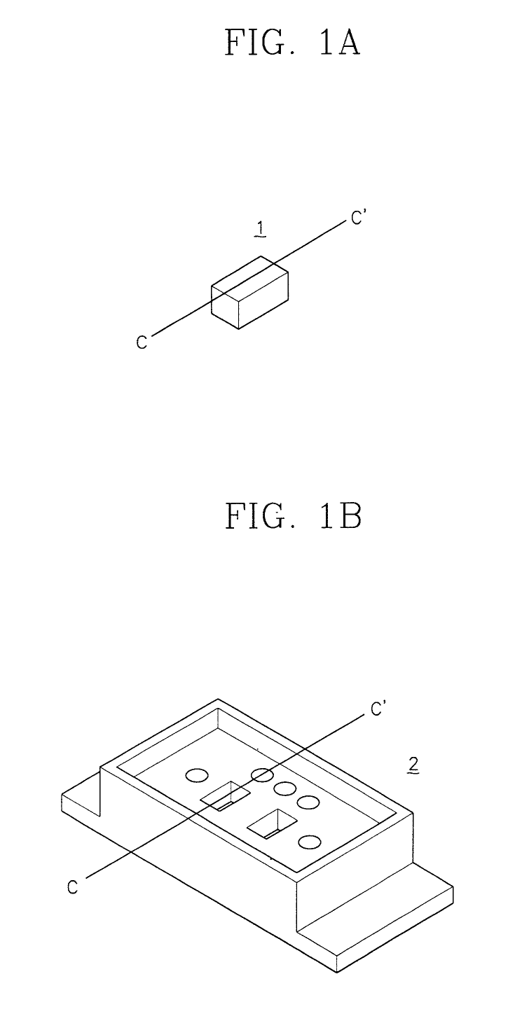

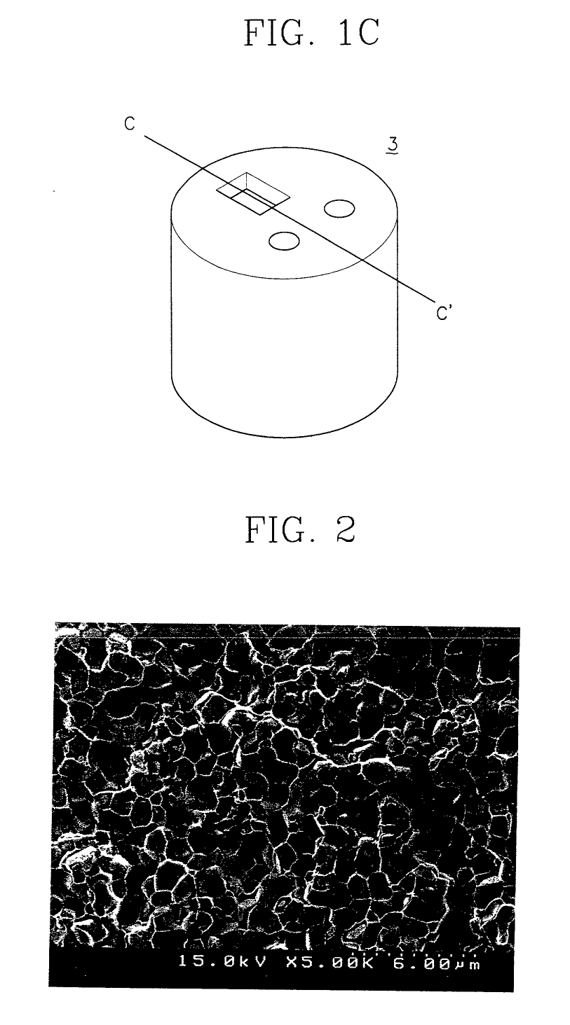

FIGS. 1a to 1c respectively illustrate constitutional elements of a package for a microwave semiconductor, which are composed of a tungsten-copper composite produced by a powder injection molding process. Here, FIG. 1a illustrates a plate-shaped heat sink 1 which is the object of the present invention, FIG. 1b illustrates a bottom plate 2 for a container for packaging a high power semiconductor device which has a walled space structure, and FIG. 1c illustrates a metal header 3 for mounting a laser diode. A typical microstructure taken along line C-C′ of the above mentioned components 1, 2 and 3 is shown in FIG. 2.

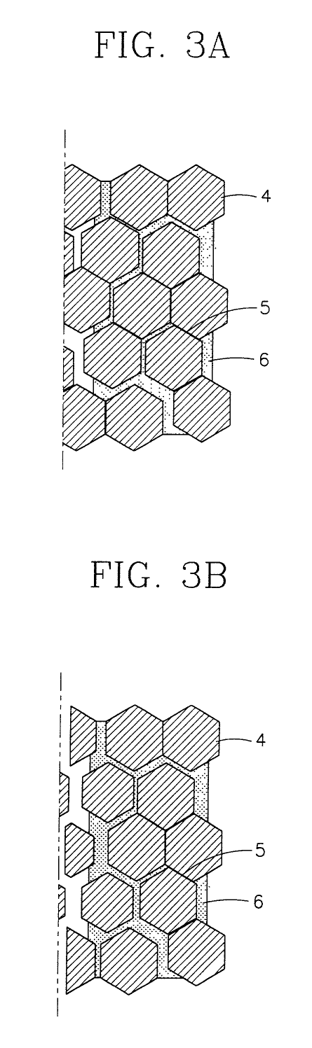

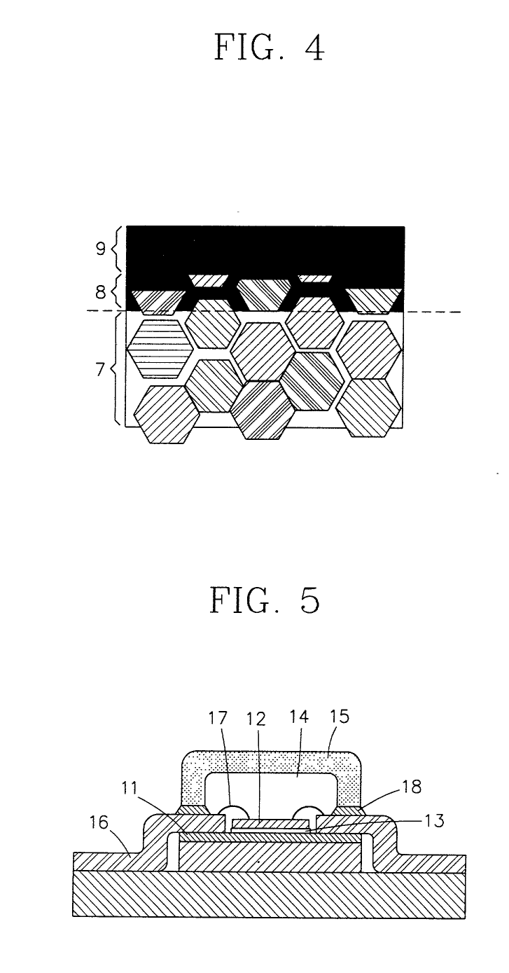

In case only copper is etched from the surface of the heat sink 1 having the microstructure as shown in FIG. 2 to modify the surface thereof, the surface of the heat sink 1 has a resultant microstructure as shown in the schematic cross-sectional view of FIG. 3a. In case tungsten grains are polished and etched from the surface of the heat sink 1 and the copper is etched therefrom to modify the surface thereof, the surface of the heat sink 1 has a resultant microstructure as shown in the schematic cross-sectional view of FIG. 3b. The reference numeral 4 indicates tungsten grains, 5 indicates a grain boundary between tungsten grains, and 6 indicates copper in FIGS. 3a and 3b. In case the surface of the heat sink 1 having the microstructure as shown in FIG. 3a and 3b is coated with a diamond film, a coating having superior adhesion can be obtained due to the interlocking structure of interface. Here, the reference numeral 7 indicates a matrix of heat sink 1 comprising a tungsten-copper composite, 9 indicates a diamond film coated on the surface thereof and 8 indicates the grain boundary portion enabling to interlock the matrix 9 of the composite heat sink with the diamond film 7.

FIG. 5 is a cross-sectional view which schematically illustrates a heat sink coated with a diamond film in accordance with the present invention used in a plastic package for semiconductor device. Here, the reference numeral 11 indicates the heat sink coated with the diamond film, 12 indicates a semiconductor device, 13 indicates solder or adhesives, 14 indicates empty structure, 15 indicates lid, 16 indicates a lead for an external wiring, 17 indicates wiring between the semiconductor 13 and the lead 16, and 18 indicates an adhesive.

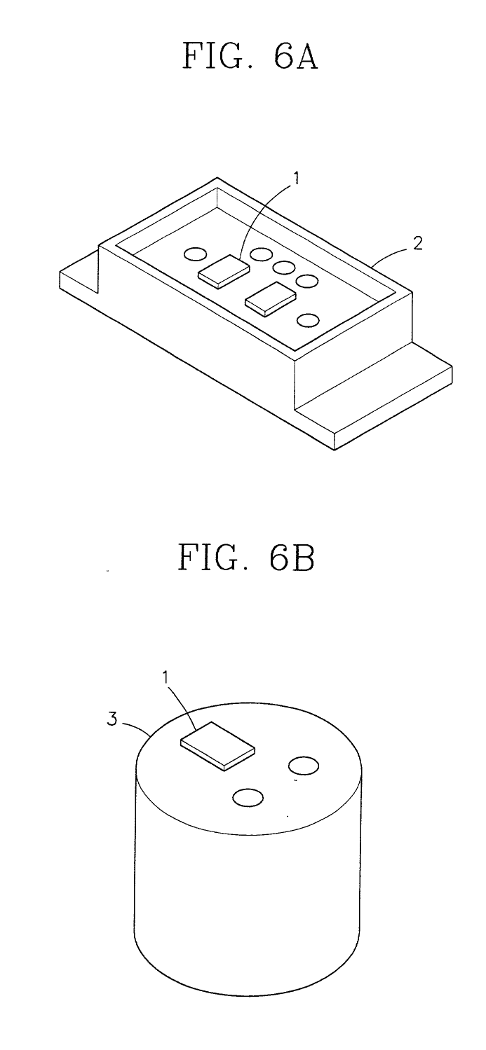

FIGS. 6a and 6b are perspective views respectively illustrating another embodiment of a heat sink coated with a diamond film in accordance with the present invention. That is, FIG. 6a illustrates a state of bonding a plate-shaped heat sink coated with a diamond film in accordance with the present invention to the space for the heat sink in the bottom plate of the container for packaging a high power semiconductor device of FIG. 1b, and FIG. 6b illustrates a state of bonding a plate-shaped heat sink coated with a diamond film in accordance with the present invention to the space for the heat sink in the metal header for mounting a laser diode of FIG. 1c.

In accordance with the present invention, the net-shaped tungsten skeleton structure is fabricated by the powder injection molding process. The liquid phase copper is infiltrated into the structure, and thus the tungsten-copper composite heat sink is fabricated. Then, the surface of the heat sink is chemically and physically modified, and a diamond film coating having excellent thermal conductivity is provided, thereby improving the thermal conductivity of the heat sink. In addition, the diamond film itself has an insulating property, and thus an insulation layer is not required which is otherwise necessary to provide insulation for the terminals for the external wiring or the wiring itself in a plastic packaging process. Accordingly, the packaging density can be lowered.

### EXAMPLE 1

A tungsten powder having an average particle size of 1.8 Φ or 2.4 Φ was mixed with a polymer binder. The mixing ratio thereof was in the range of 46% to 54% by volume. A feed stock produced in the above-mentioned manner was injection-molded in the forms illustrated in FIGS. 1a to 1c and debinded, whereby green preformed parts composed solely of tungsten were obtained.

The green preforms were then sintered under flowing hydrogen at 1500EC for 20 hours. The porosity of the sintered parts was measured as 28% and 35∀1%, respectively. A copper liquid phase was infiltrated into the pores at 1150EC under a hydrogen atmosphere. In order to coat the plate-shaped tungsten-copper composite heat sink in FIG. 1a with a diamond film, the heat sink was soaked in 40% HNO₃ for 2 to 5 minutes, and thus the copper was dissolved from the surfaces thereof. FIG. 3a illustrates a cross-sectional view of the surface structure of the heat sink from which the copper was dissolved. After the chemical etching of the surface, an ultrasonic treatment was carried out in an acetone solution containing 0.5 Φ diamond powder for 2 minutes, and thus the nuclei for the growth of diamond were distributed on the etched surface. The diamond film was deposited by the microwave PACVD method (microwave plasma assisted chemical vapor deposition) using CH₄ gas of 5% in H₂ at 950EC for 5 hours. The plate-shaped tungsten-copper composite heat sink coated with diamond (FIG. 1a) was positioned in a space in the heat sink shown in FIG. 1b or 1c. Then, the heat sink was heated under an argon atmosphere at 1100E for 30 minutes, and thus a direct bonding was accomplished across the interface between the heat sink and the space. After the direct bonding was completed, the heat sink was slowly cooled to the ambient temperature at a speed of 10° C./min.

### EXAMPLE 2

On the other hand, a heat sink for a high power semiconductor device having a layer of diamond film and a fabrication method therefor in accordance with a second embodiment of the present invention will now be described.

First, a tungsten-copper composite was prepared in the same manner as in the first example. Before dissolving the surface copper by using 40% HNO₃, surface tungsten particles were etched by employing a Murakami solution (potassium ferricyanide[K₃Fe(CN)₆]+sodium hydroxide[NaOH]+water[H₂O]) for 3 to 5 minutes, thereby forming a roughened surface among the tungsten grains, as illustrated in FIG. 3b. Then, the surface was modified by dissolving the copper therefrom with the 40% HNO₃. Identically to the first example, a tungsten-copper composite layered with diamond was obtained by coating the surface with a diamond film. The plate-shaped tungsten-copper composite coated with the diamond film was positioned at a space in the heat sink of FIG. 1b or 1c. The composite was heated under an argon atmosphere at 1100EC for 30 minutes, and thus direct bonding was accomplished between the heat sink and the bottom side of the airtight container. The heat sink was then slowly cooled down to the ambient temperature at a speed of 10EC per minute.

As the present invention may be embodied in several forms without departing from the spirit of essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the meets and bounds of the claims, or equivalence of such meets and bounds are therefore intended to be embraced by the appended claims.

What is claimed is:

1. A heat sink for a semiconductor device, comprising:
a) a tungsten-copper composite body; and
b) a diamond film coated on the surface of the body.

2. A method for fabricating a heat sink for a semiconductor, comprising:
a) fabricating a tungsten-copper composite heat sink;
b) modifying a surface of the heat sink by selectively dissolving copper from the surface of the heat sink;
c) carrying out a process for supplying nuclei for growth of a diamond film on the modified surface of the heat sink; and
d) coating the thusly processed surface of the heat sink with a diamond film.

3. The method of claim 2, wherein a process for etching tungsten grains precedes selective dissolution of the copper.

4. The method of claim 2 or 3, wherein the copper is dissolved in an aqueous acid solution comprising HNO₃.

5. The method of claim 2 or 3, wherein the process for supplying nuclei for growth of the diamond film is carried out in an acetone solution containing fine diamond powder.

6. The method of claim 3, wherein the process for etching the tungsten grains is carried out in a Murakami solution (potassium ferricyanide [K₃Fe(CN)₆]+sodium hydroxide[NaOH]+water[H₂O]).
